(19) United States
(12) Patent Application Publication
(10) Pub. No.: US 2006/0148263 A1
(43) Pub. Date: Jul. 6, 2006

(54) Dry etching apparatus having particle removing device and method of fabricating phase shift mask using the same

(76) Inventors: Yo-han Choi, Gyeonggi-do (KR); Il-yong Jang, Gyeonggi-do (KR); Jeong-yun Lee, Gyeonggi-do (KR)

Correspondence Address: HARNESS, DICKEY & PIERCE, P.L.C., P.O. BOX 8910, RESTON, VA, 20195, US

(21) Appl. No.: 11/324,281

(22) Filed: Jan. 4, 2006

(30) Foreign Application Priority Data
Jan. 5, 2005 (KR) 10-2005-0000995

(51) Int. Cl. H01L 21/461

(52) U.S. Cl. 438/706; 156/345.45

(57) ABSTRACT

A dry etching apparatus may include a dry etching chamber and a door chamber. The apparatus may further include a load lock chamber configured to connect the dry etching chamber and the door chamber in a vacuum state. A gas injector and an ionizer may be configured inside the door chamber or the load lock chamber. A gas supplying source may be disposed out of the chambers to supply a determined gas to the gas injector and the ionizer. A method of fabricating a phase shift mask using the dry etching apparatus may include removing particles attached to the surface of a mask in the door chamber or the load lock chamber during an etch process by the gas injector and the ionizer configured inside the door chamber or the load lock chamber of the etching apparatus.

### PRIORITY CLAIM

A claim of priority is made to Korean Patent Application No. 10-2005-0000995, filed Jan. 5, 2005, the disclosure of which is hereby incorporated herein by reference in its entirety.

### BACKGROUND OF INVENTION

1. Technical Field

Example embodiments of the present invention generally relate to a semiconductor manufacturing apparatus and a method of fabricating a photo mask using the same. More particularly, example embodiments of the present invention relate to a dry etching apparatus having a particle removing device and a method of fabricating a phase shift mask using the same.

2. Discussion of the Related Art

With semiconductor devices scaling down in size, pattern sizes on the devices have also been reduced. However, a conventional chrome (Cr) mask, used to pattern layers may be insufficient to provide high resolution to form appropriate size patterns. To achieve higher resolution, light having a short wavelength may be employed during an exposure process, or an exposure apparatus having a larger numerical aperture (NA) may be used. These methods may be difficult to apply, require addition process time, and/or may be expensive. A phase shift mask (PSM) has been used to pattern layers, because a PSM may provide a more efficient method of increasing resolution while using existing exposure apparatuses.

A phase shift mask may include a phase shift pattern. A method of forming a pattern using the phase shift mask is based on a principle that light passing through a portion of the phase shift pattern and light passing through another portion respectively come together to form a phase difference of 180° so as to cause an off-set interference.

To fabricate a phase shift mask, a phase shift layer and a light shield layer may be sequentially formed on a substrate. A photoresist layer may be deposited on the light shield layer, and electron beam may be irradiated thereon to expose the photoresist layer. The exposed photoresist layer may be developed to form a photoresist pattern, and the light shield layer may be etched using the photoresist pattern as an etch mask to form a light shield layer pattern on the phase shift layer. The phase shift layer may be further dry-etched using the light shield layer pattern as an etch mask to form a phase shift layer pattern.

FIG. 1 is a process flow chart illustrating a method of fabricating a phase shift mask using a conventional dry etching apparatus.

FIGS. 2A to 2G are sectional views illustrating a conventional method of fabricating a phase shift mask.

Referring to FIGS. 1 and 2A, a blank mask sample may have a phase shift layer 10 and a light shield layer 20 sequentially stacked on a transparent quartz substrate 5. The light shield layer 20 may be formed of chrome. The phase shift layer 10 may be formed of MoSiON.

Referring to FIGS. 1 and 2B, a photoresist layer may be deposited on the light shield layer 20, and electron beam may be irradiated to expose the photoresist layer. The exposed photoresist layer may be developed to form a photoresist pattern. The light shield layer 20 may be etched using the photoresist pattern as an etch mask to form a light shield layer pattern 20a on the phase shift layer 10. The photoresist pattern may be removed.

The blank mask sample having the light shield layer pattern 20a may be loaded into a door chamber (P1 of FIG. 1) of an etching apparatus. The interior of the door chamber may be pumped (P2 of FIG. 1) to create a vacuum inside of the door chamber. The blank mask sample may be transferred to a load lock chamber (P3 of FIG. 1). At this time, the load lock chamber may also be in a vacuum state. After the formation of the light shield layer pattern 20a, particles PA1 may form on the blank mask sample during a subsequent process.

Referring to FIGS. 1 and 2C, after transferring the blank mask sample from the load lock chamber to a dry etching chamber, the phase shift layer 10 may be dry-etched using the light shield layer pattern 20a as an etch mask (P4 of FIG. 1). As a result, a first etched phase shift layer 10a may be formed. The particles PA1 may be negatively charged by plasma discharge used in the etching process.

The phase shift layer 10 may be non-uniformly etched after the first etch process due to the particles PA1. In an enlarged view of region “A”, a phase shift layer region R2 below the particle PA1 may not be etched due to the particle PA1 whereas region R1 free of the particle PA1 may be etched. The first etch process should not fully expose the quartz substrate 5 below the phase shift layer 10. If the phase shift layer 10 is fully etched by a single etch process, a phase shift layer, which may be different than the light shield layer pattern 20a, may be formed due to the particles PA1.

The first etched blank mask sample may be transferred back to the load lock chamber (P5 of FIG. 1). The blank mask sample may be transferred from the load lock chamber to the door chamber. The interior of the door chamber may be vented to create an atmosphere condition (P6 of FIG. 1). The blank mask sample may be unloaded from the vented door chamber.

Referring to FIGS. 1 and 2D, the blank mask sample may be examined to determine whether the pattern on the blank mask sample has been completely formed (P8 of FIG. 1). If the pattern has not been completely formed, a wet cleaning process is performed to remove the particles PA1 (P81 of FIG. 1). FIG. 2D is a sectional view illustrating a blank mask sample after the particles PA1 have been removed.

Referring to FIGS. 1 and 2E, the blank mask sample may be reloaded to the door chamber (P1 of FIG. 1). Then, P2, P3 and P4 of FIG. 1 may be repeated, and thus, the etched phase shift layer 10a may be etched again using the light shield layer pattern 20a as an etch mask. As a result, a second etched phase shift layer 10b may be formed. However, the second etching process may create new particles PA2, which attach to the blank mask sample. The particles PA2 may also be negatively charged due to the plasma discharge used during the etching process.

An enlarge view of region “A” illustrates region R2 where the particles PA1 previously existed and region R1 free of the particles PA1 as described with respect to FIG. 2C.

Referring to FIGS. 1 and 2F, FIG. 2F illustrates a sectional view of the blank mask sample after removing the particles PA2 by repeating P5, P6, P7, P8, and P81.

Referring to FIGS. 1 and 2G, the etch processes on the blank mask sample and the particle removing process by wet cleaning as described in FIGS. 2C to 2F may be repeated several times to form a phase shift layer pattern 10c having the same shape as that of the light shield layer pattern 20a.

### SUMMARY OF THE INVENTION

In an example embodiment of the present invention, a dry etching apparatus includes a dry etching chamber, a door chamber, and a load lock chamber configured to connect the dry etching chamber to the door chamber. A particle removing device may be disposed inside the door chamber or the load lock chamber. A gas supplying source may be coupled to the door chamber or the load lock chamber and adapted to supply gas to the particle removing device

In another example embodiment, a method of fabricating a phase shift mask includes loading a blank mask sample having a light shield layer pattern formed on a substrate thereon into a door chamber, transferring the blank mask sample to a dry etching chamber, etching the phase shift layer using the light shield layer pattern as an etch mask, examining the blank mask sample to determine whether a pattern has been completely formed, and removing particles on the blank mask sample by gas supplied by an injector.

Example embodiments of the present invention are directed to a dry etching apparatus having a particle removing device suitable to reduce process time required to remove particles during formation of a phase shift layer pattern in a process of forming a phase shift mask and reducing production expenses, and a method of fabricating a phase shift mask using the same.

In accordance with an example embodiment, the present invention provides a dry etching apparatus having a particle removing device. The dry etching apparatus may include a dry etching chamber and a door chamber. A load lock chamber may be disposed to connect the dry etching chamber and the door chamber in a vacuum state. A gas injection part and an ionizer may be disposed inside the door chamber or the load lock chamber. A gas supplying source may be disposed outside of the chambers to supply a gas to the gas injection part and the ionizer. A gas supplying line may be disposed to connect the gas supplying source and the gas injection part and the ionizer.

The ionizer, the gas injection part, the gas supplying line, and the gas supplying source may constitute a particle removing device.

A filter part may be installed to the gas supplying line between the gas supplying source and the chamber to clean the gas passing through the gas supplying line.

Substrate stages for mounting an etched object thereon may be disposed inside the dry etching chamber, the load lock chamber, and the door chamber.

The gas injection part and the ionizer may be disposed in parallel with each other. The gas injection part and the ionizer may be disposed in a bar shape such that injection openings of the gas injection part and injection openings of the ionizer are alternately disposed. The bar may be disposed over the substrate stage to be spaced there from with a predetermined distance.

Directions of the injection openings of the gas injection part and the injection openings of the ionizer may be directed toward the substrate stage, and may have an angle inclined toward a pumping direction. The bar may scan along a direction in parallel with the substrate stage. A gas introduced into the gas injection part may use nitrogen, air, CO₂ ice, or H₂O gas. A gas introduced into the ionizer may use air.

Alternatively, the gas injection part and the ionizer may be disposed in series. An ionized gas passing through the ionizer may be used as a gas of the gas injection part. A gas introduced into the ionizer may use air. The gas injection part and the ionizer may be disposed in a bar shape such that injection openings of the gas injection part are in a line. The bar may be disposed over the substrate stage and spaced there from by a given distance. In an example embodiment, a direction of the injection openings of the gas injection part may be directed toward the substrate stage, and may have an angle inclined toward a pumping direction. The bar may scan along a direction in parallel with the substrate stage.

In another example embodiment, the present invention may be directed to a method of fabricating a phase shift mask using a dry etching apparatus having a particle removing device. The method may include preparing a blank mask having a structure in which a phase shift layer and a light shield layer are sequentially stacked on a quartz substrate. The light shield layer may be patterned, thereby forming a light shield layer pattern. The blank mask having the light shield layer pattern formed thereon may be loaded to a door chamber. The door chamber may be pumped to maintain the door chamber in a vacuum state. The blank mask may be moved through a load lock chamber to a dry etching chamber with a vacuum state. The phase shift layer may be etched inside the dry etching chamber, using the light shield layer pattern as an etch mask. The blank mask having the etched phase shift layer may be moved through the load lock chamber to the door chamber in a vacuum state. Particles on the etched phase shift layer may be removed inside the door chamber, using an ionizer and a gas injection part disposed inside the door chamber. The blank mask from which particles are removed may be moved through the load lock chamber to the dry etching chamber. The blank mask free of particles may then be etched again.

In another example embodiment, the phase shift layer etching and the particle removing operations may be performed repeatedly (for example, at least two times).

In another example embodiment, the phase shift layer etching and the particle removing operations are preferably performed with a vacuum state maintained.

In another example embodiment, the particles on the phase shift layer may be charged when etching the phase shift layer using the light shield layer pattern as an etch mask inside the dry etching chamber.

In an example embodiment, an operation of removing particles on the etched phase shift layer inside the door chamber, using an ionizer and a gas injection part disposed inside the door chamber may include injecting an ionized gas passing through the ionizer to neutralize the charged particles on the etched phase shift layer. The gas injected from the gas injection part may blow the neutralized particles on the etched phase shift layer, thereby removing the neutralized particles.

In another example embodiment, an operation of removing particles on the etched phase shift layer inside the door chamber, using an ionizer and a gas injection part disposed inside the door chamber may include injecting an ionized gas, which passed through the ionizer, through the gas injection part to neutralize the charged particles on the etched phase shift layer, and concurrently, to blow the particles, thereby removing the charged particles on the firstly etched phase shift layer.

In an example embodiment, the light shield layer may be formed of a chrome layer.

In an example embodiment, the phase shift layer may be formed of a material layer having an etch selectivity with respect to the quartz substrate. The phase shift layer may be formed of a material layer selected from the group consisting of MoSiON, MoSi₂, and Mo.

In another example embodiment, the present invention provides a method of fabricating a phase shift mask using a dry etching apparatus having a particle removing device. The method may include preparing a blank mask having a structure in which a phase shift layer and a light shield layer are sequentially stacked on a quartz substrate. The light shield layer may be patterned, thereby forming a light shield layer pattern. The blank mask having the light shield layer pattern formed thereon may be loaded to a door chamber. The door chamber may be pumped to maintain the door chamber in a vacuum state. The blank mask may be moved through a load lock chamber to a dry etching chamber in a vacuum state. The phase shift layer may be etched inside the dry etching chamber, using the light shield layer pattern as an etch mask. The blank mask having the etched phase shift layer may be moved to the load lock chamber in a vacuum state. Particles on the firstly etched phase shift layer may be removed inside the load lock chamber, using an ionizer and a gas injection part disposed inside the load lock chamber. The blank mask from which particles are removed may be moved to the dry etching chamber to perform another etching.

In an example embodiment, the phase shift layer etching and the particle removing operations may be performed repeatedly (for example, at least two times).

In an example embodiment, the phase shift layer etching and the particle removing operations may be performed with a vacuum state maintained.

In an example embodiment, the particles on the phase shift layer may be charged when etching the phase shift layer using the light shield layer pattern as an etch mask inside the dry etching chamber.

In an example embodiment, an operation of removing particles on the etched phase shift layer inside the load lock chamber, using an ionizer and a gas injection part disposed inside the load lock chamber may include injecting an ionized gas passing through the ionizer to neutralize the charged particles on the etched phase shift layer. The gas injected from the gas injection part may blow the neutralized particles on the etched phase shift layer, thereby removing the neutralized particles.

In another example embodiment, an operation of removing particles on the etched phase shift layer inside the load lock chamber, using an ionizer and a gas injection part disposed inside the load lock chamber may include injecting an ionized gas, which passed through the ionizer, through the gas injection part to neutralize the charged particles, and concurrently, to blow the particles, thereby removing the charged particles on the etched phase shift layer.

In an example embodiment, the light shield layer may be formed of a chrome layer.

In an example embodiment, the phase shift layer may be formed of a material layer having an etch selectivity with respect to the quartz substrate. The phase shift layer may be formed of a material layer selected from the group consisting of MoSiON, MoSi₂, and Mo.

### BRIEF DESCRIPTION OF THE DRAWINGS

The present invention will become more apparent to those of ordinary skill in the art with the description of example embodiments thereof with reference to the attached drawings in which:

FIG. 1 is a process flow chart illustrating a method of fabricating a phase shift mask using a conventional dry etching apparatus;

FIGS. 2A to 2G are sectional views illustrating a conventional method of fabricating a phase shift mask;

FIG. 3 is a schematic view illustrating a dry etching apparatus having a particle removing device according to an example embodiment of the present invention;

FIGS. 4A and 4B are schematic views illustrating particle removing devices according to example embodiments of the present invention;

FIG. 5 is a perspective view illustrating a gas injector and an ionizer of FIG. 4B;

FIG. 6 is a process flow chart illustrating a method of fabricating a phase shift mask using a dry etching apparatus according to an example embodiment of the present invention;

FIGS. 7A to 7G are sectional views illustrating a method of fabricating a phase shift mask using the dry etching apparatus according to an example embodiment of the present invention; and

FIG. 8 is a process flow chart illustrating a method of fabricating a phase shift mask using a dry etching apparatus according to still another embodiment of the present invention.

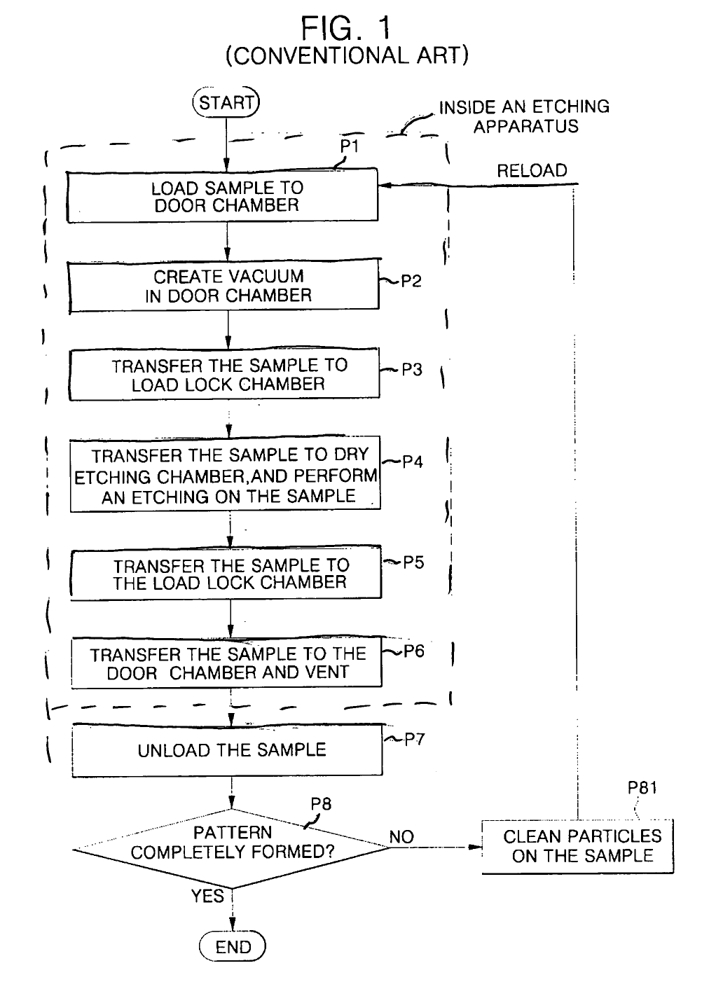

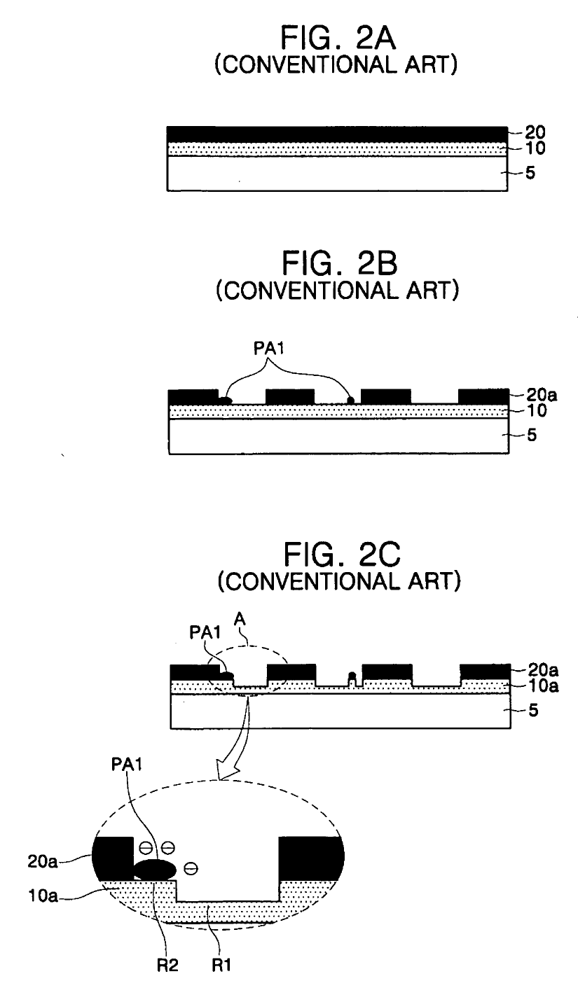

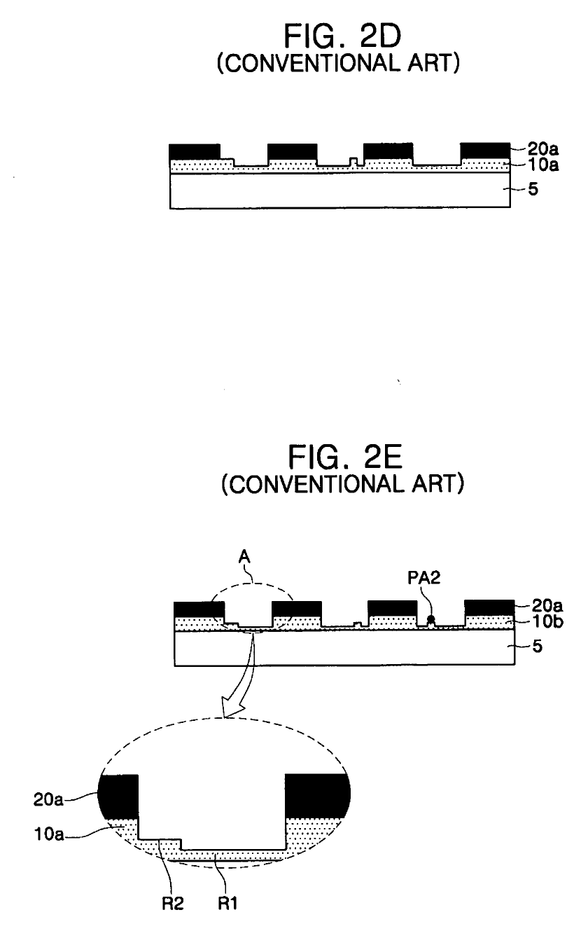

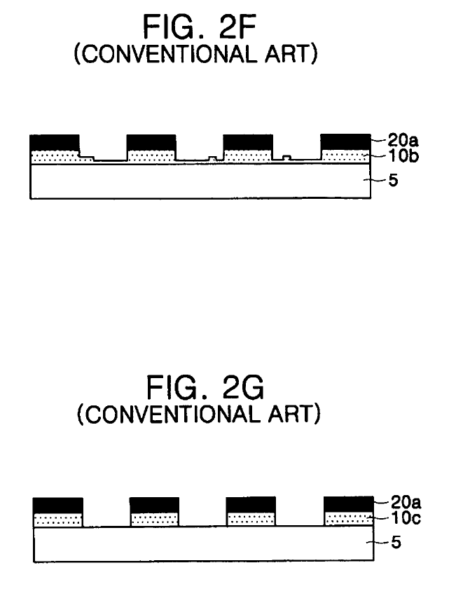

### DETAILED DESCRIPTION OF EXAMPLE EMBODIMENTS

The present invention will now be described more fully hereinafter with reference to the accompanying drawings, in which example embodiments of the present invention are shown. The present invention may, however, be embodied in many different forms and should not be construed as being limited to the example embodiments set forth herein. In the drawings, the thickness of layers and regions may be exaggerated for clarity. Like numbers refer to like elements throughout the specification.

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there may be no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that may be schematic illustrations of idealized embodiments (and intermediate structures) of the present invention. As such, variations from the shapes of the illustrations as a result, for example, of manufacturing techniques and/or tolerances, are to be expected. Thus, the example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

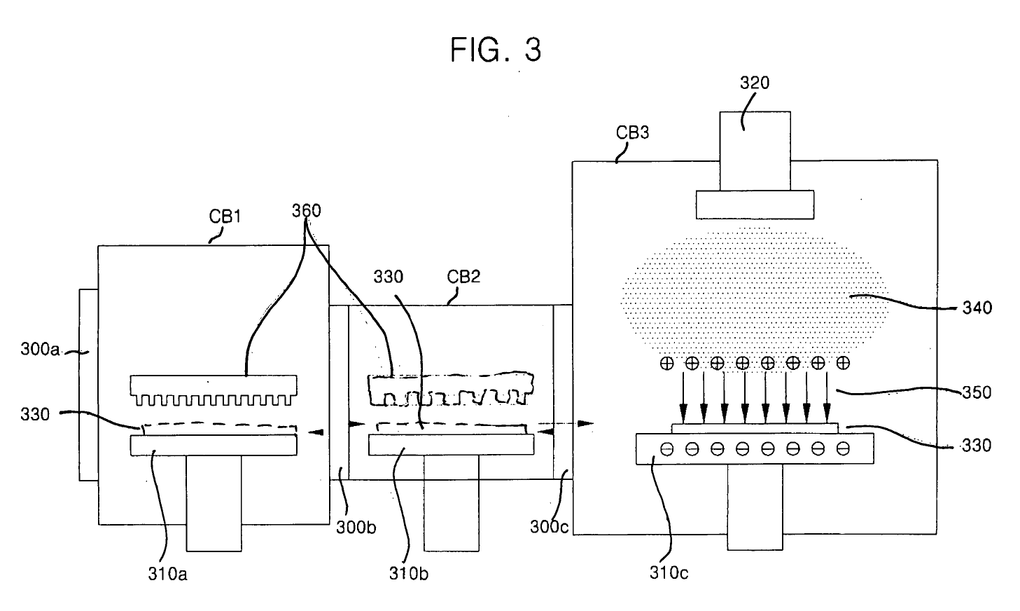

FIG. 3 is a schematic view illustrating a dry etching apparatus having a particle removing device according to an example embodiment of the present invention.

Referring to FIG. 3, the dry etching apparatus may include a dry etching chamber CB3 and a door chamber CB1. A load lock chamber CB2 capable of being in a vacuum state may be disposed between the dry etching chamber CB3 and the door chamber CB1. Substrate stages 310a, 310b, 310c configured to mount an etching sample 330 thereon may be disposed inside the door chamber CB1, the load lock chamber CB2, and the dry etching chamber CB3, respectively. A door 300a to be used to facilitate the loading and unloading of the etching sample 330 may be configured at a side of the door chamber CB1. Middle doors 300b, 300c may be disposed between the door chamber CB1 and the load lock chamber CB2, and between the load lock chamber CB2 and the dry etching chamber CB3, respectively. The middle doors 300b, 300c may assist in maintaining vacuum inside the various chambers.

A power supplier 320 to generate plasma 340, may be disposed in the dry etching chamber CB3. The power supplier 320 may apply voltage to the substrate stage 310c inside the dry etching chamber CB3 during an etching process. When plasma 340 is generated, a sheath layer 350 may be formed around the plasma 340. The sheath layer 350 has a negative charge because it has a lower potential as compared to a potential Vp of the plasma 340. Hence, positive ions inside the plasma 340 are accelerated in the sheath layer 350, and the positive ions etch the etching sample 330.

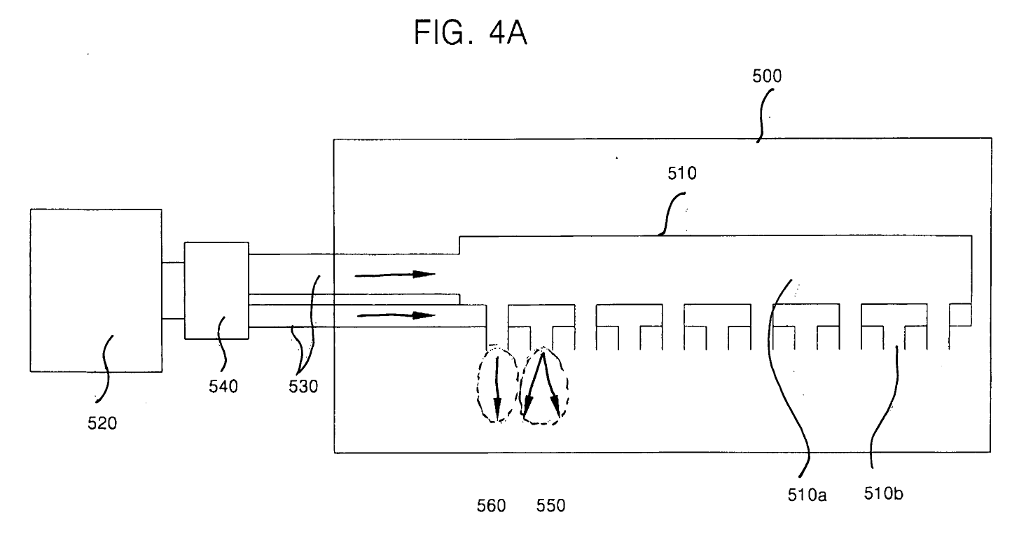

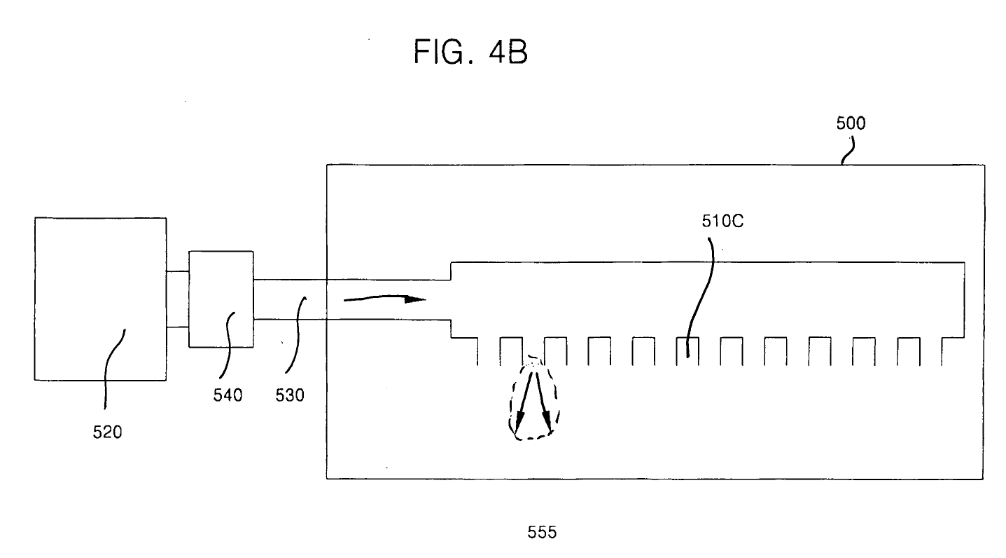

A particle removing device 360 may include a gas injector and an ionizer (FIG. 4A) and may be disposed inside the door chamber CB1 and/or the load lock chamber CB2. The particle removing device 360 may be configured and spaced away at a desired distance above the substrate stages 310a, 310b.

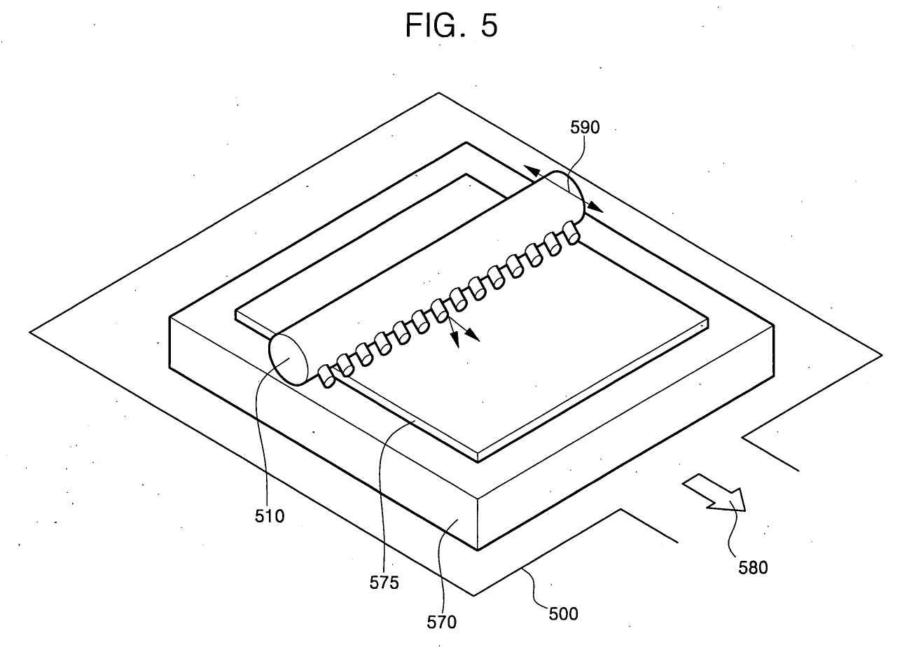

FIGS. 4A and 4B are schematic views illustrating particle removing devices according to example embodiments of the present invention. FIG. 5 is a perspective view illustrating a gas injector and an ionizer of FIG. 4B.

Referring to FIG. 4A, a gas supplying source 520 configured to supply gas into a particle removing device 510 which may include a gas injector 510a and an ionizer 510b, and may be disposed outside a chamber 500. A gas supplying line 530 may be configured to connect the gas supplying source 520 to the gas injector 510a and the ionizer 510b. The gas injector 510a and the ionizer 510b may be connected to separate gas supplying sources.

A filter 540 may be installed on the gas supplying line 530 and between the gas supplying source 520 and the chamber 500 to filter and clean the gas passing through the gas supplying line(s) 530. Gas introduced into the gas injector 510a may include nitrogen, air, CO₂ ice, H₂O gas, or a combination thereof. Gas introduced into the ionizer 510b may include air.

The gas injector 510a and the ionizer 510b may be configured in parallel with each other. The injection openings of the gas injector 510a may inject gas with a desired pressure 560. The injection openings of the ionizer 510b may inject ionized gas 550.

As shown in FIGS. 4B and 5, a cylindrical bar injector 510c may be disposed over and spaced away from the substrate stage 570 at a desired distance. An etched sample 575 may be disposed on the substrate stage 570. A direction of the injection openings of the cylindrical bar injector 510c may be directed toward the etched object 575, and may be at an angle inclined toward a pumping direction 580. The cylindrical bar injector 510c may scan along a direction 590 in parallel with the substrate stage 570. It should be noted that the gas injector 510a and ionizer 510b illustrated in FIG. 4A may also include these features.

In the example embodiment illustrated in FIGS. 4B and 5, the gas injector and the ionizer are combined to form a single cylindrical bar injector. The injection openings of the cylindrical gas injector 510c may inject gas with a desired pressure 555.

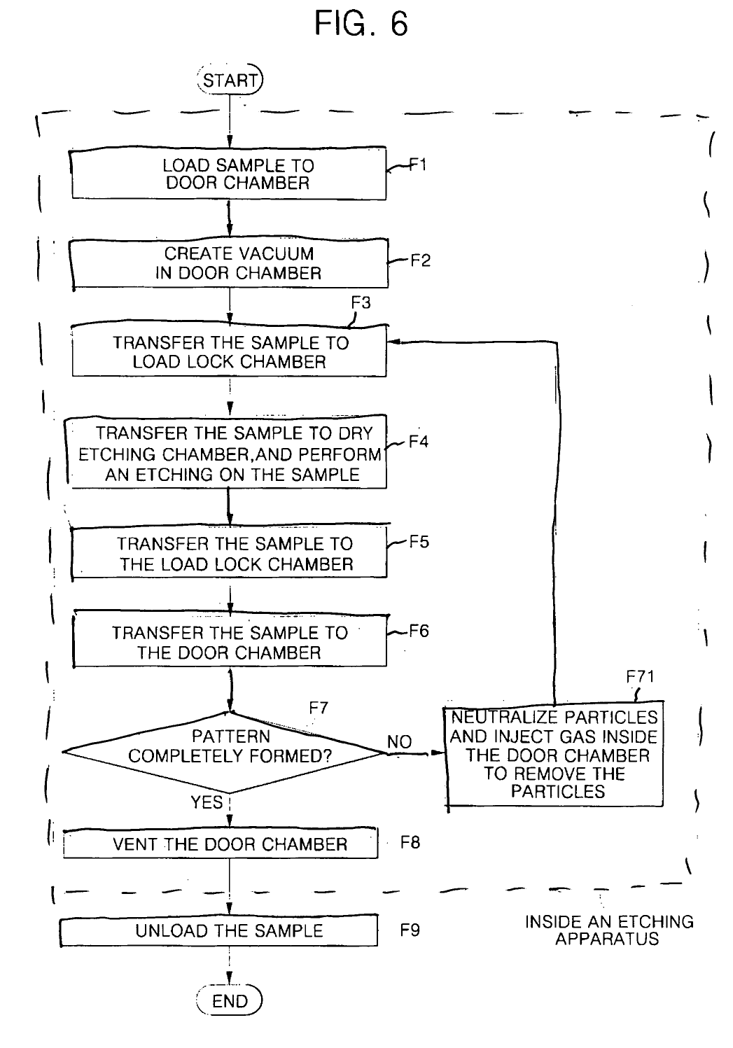

FIG. 6 is a process flow chart illustrating a method of fabricating a phase shift mask using a dry etching apparatus according to an example embodiment of the present invention.

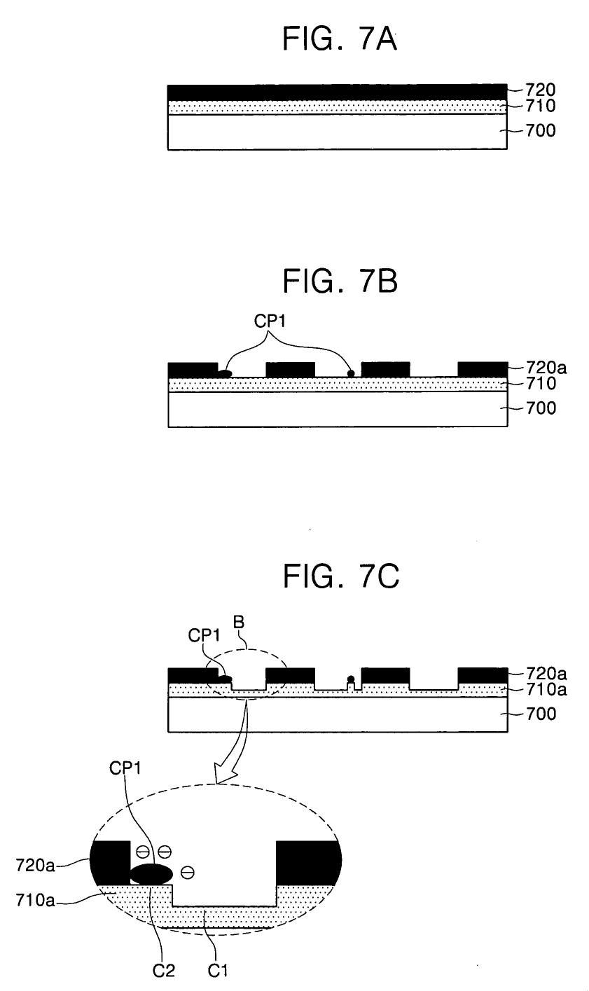

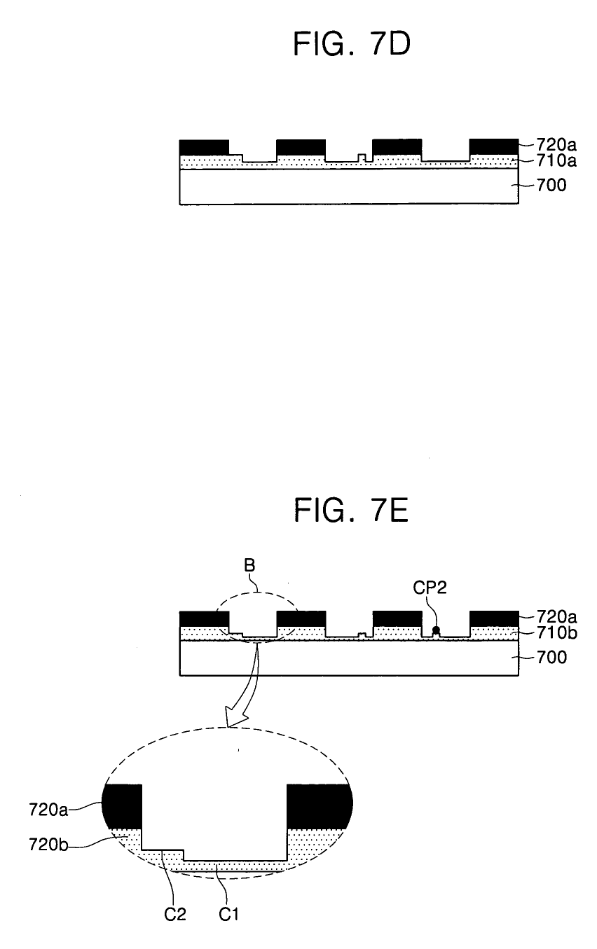

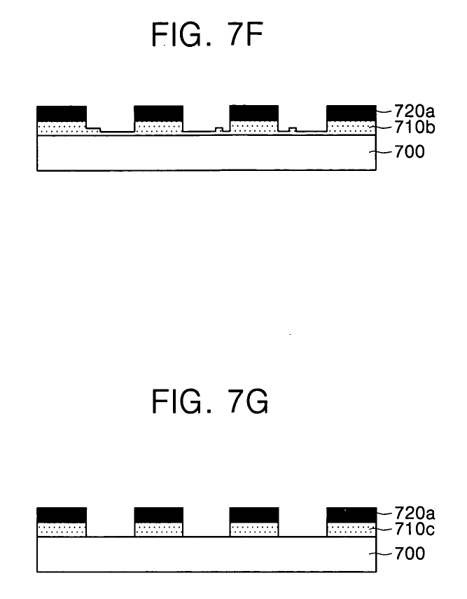

FIGS. 7A to 7G are sectional views illustrating a method of fabricating a phase shift mask using the dry etching apparatus according to an example embodiment of the present invention.

Referring to FIGS. 6 and 7A, a blank mask sample may have a sequentially stacked phase shift layer 710 and a light shield layer 720 on a transparent quartz substrate 700. The light shield layer 720 may be formed of chrome. The phase shift layer 710 may be formed of a material layer having an etch selectivity with respect to the quartz substrate 700. The phase shift layer 710 may be formed of a material of MoSiON, MoSi2, and/or Mo.

Referring to FIGS. 6 and 7B, after depositing a photoresist layer on the light shield layer 720, an electron beam may be irradiated on the photoresist layer to expose the photoresist. The exposed photoresist layer may be developed to form a photoresist pattern. The light shield layer 720 may be etched using the photoresist pattern as an etch mask to form a light shield layer pattern 720a on the phase shift layer 710. The photoresist pattern may be removed.

The blank mask sample having the light shield layer pattern 720a may be loaded into a door chamber (F1 of FIG. 6). The door chamber having the loaded blank mask sample therein may be pumped to create a vacuum inside of the door chamber (F2 of FIG. 6). The blank mask sample may be transferred to a load lock chamber (F3 of FIG. 6). The load lock chamber may also be in a vacuum state. After the formation of the light shield layer pattern 720a, particles CP1 may form on the blank mask sample during a subsequent process.

Referring to FIGS. 6 and 7C, after transferring the blank mask sample from the load lock chamber to a dry etching chamber, the phase shift layer 710 may be dry-etched using the light shield layer pattern 720a as an etch mask (F4 of FIG. 6). As a result, a first etched phase shift layer 710a may be formed. At this time, particles CP1 may be attached to the blank mask during the etch process. The particles CP1 may be negatively charged by plasma discharge during the etch process.

The phase shift layer 710 may be non-uniformly etched due to the particles CP1 during the etch process. In an enlarged view of region “B,” a phase shift layer region C2 under the particles CP1 may not be etched, but region C1 free of the particles CP1 may be etched. The phase shift layer 710 may only be partially etched. If the phase shift layer 710 is completely etched by a single etch process, a phase shift layer pattern different from the light shield layer pattern 720a may be formed due to the particles CP1.

The blank mask sample having the partially first etched phase shift layer 710a may be transferred to the load lock chamber (F5 of FIG. 6). The mask sample may be transferred from the load lock chamber to the door chamber (F6 of FIG. 6).

Referring to FIGS. 6 and 7D, the blank mask sample may be examined to determine whether a pattern on the blank mask sample has been completely formed (F7 of FIG. 6), and if the pattern has not been completely formed, the particles CP1 of the blank mask sample may be removed using the particle removing device, e.g., the gas injector and the ionizer described with reference to FIGS. 4A, 4B, and 5 (F71 of FIG. 6). FIG. 7D illustrates the blank mask sample having the particles CP1 removed.

In the process of removing the particles CP1 on the first etched phase shift layer 710a using the ionizer and the gas injector, ionized gas passing through the ionizer may neutralize the charged particles CP1 on the first etched phase shift layer 710a. The neutralized particles CP1 are removed by gas injected from the gas injector.

In another example embodiment, in a process of removing the particles CP1 on the first etched phase shift layer 710a using the ionizer and the gas injector, the ionized gas passing through the ionizer passes through the gas injector neutralizes and concurrently remove the particles CP1.

Referring to FIGS. 6 and 7E, the blank mask sample from which the particles CP1 are removed may be transferred from the door chamber to the load lock chamber (F3 of FIG. 6). F4 of FIG. 6 may be repeated to etch the first etched phase shift layer 710a for a second time using the light shield layer pattern 720a as an etch mask. As a result, a second etched phase shift layer 710b may be formed. New particles CP2 may be attached to the blank mask sample during the second etch process. The particles CP2 may be negatively charged by the plasma discharge during the etch process.

As shown in region “B” of the blank mask sample, region C2 where the particles CP1 previously existed, and the region C1 free of the particles CP1 are etched again.

Referring to FIGS. 6 and 7F, FIG. 7F illustrates a sectional view of the blank mask sample after the particles CP2 are removed by again performing F5, F6, F7, and F71 of FIG. 6.

Referring to FIGS. 6 and 7G, the etch process on the blank mask sample inside the dry etching chamber, and the particle removing process inside the door chamber as described with reference to FIGS. 7C to 7F may be performed several times as need to form a phase shift layer pattern 710c that exposes the quartz substrate 700.

The interior of the door chamber may be in an atmosphere condition by venting the door chamber (F8 of FIG. 6). The blank mask sample may be unloaded from the vented door chamber (F9 of FIG. 6).

As described above, the particles attached to the surface of the blank mask sample may be removed, and the etch process may be repeated to form the phase shift pattern. The etch process and the particle removing process may be performed in-situ in example embodiments of the present invention. Therefore, as compared to the conventional art, the etching process may be more simply and/or effectively performed.

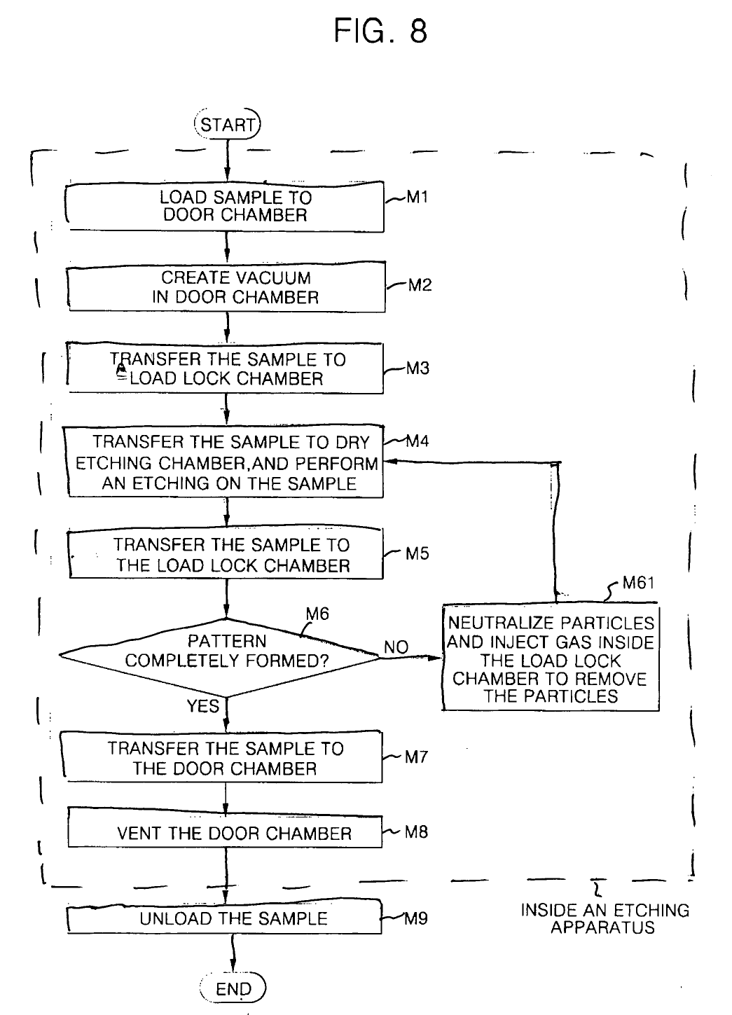

FIG. 8 is a process flow chart illustrating a method of fabricating a phase shift mask using a dry etching apparatus according to another example embodiment of the present invention.

Referring to FIGS. 7A to 7G, a method of fabricating a phase shift mask according to another example embodiment of the present invention will be described.

Referring to FIGS. 8 and 7A, a blank mask sample may have a sequentially stacked phase shift layer 710 and a light shield layer 720 on a transparent quartz substrate 700. The light shield layer 720 may be formed of chrome. The phase shift layer 710 may be formed of a material having an etch selectivity with respect to the quartz substrate 700. The phase shift layer 710 may be formed of a material selected from MoSiON, MoSi2, and Mo.

Referring to FIGS. 8 and 7B, after depositing a photoresist layer on the light shield layer 720, electron beam may be irradiated on the photoresist layer to expose the photoresist. Then, the exposed photoresist layer may be developed to form a photoresist pattern. The light shield layer 720 may be etched using the photoresist pattern as an etch mask to form a light shield layer pattern 720a on the phase shift layer 710. Then, the photoresist pattern may be removed.

The blank mask sample having the light shield layer pattern 720a may be loaded into a door chamber (M1 of FIG. 8). The door chamber having the loaded sample therein may be pumped to create a vacuum inside the door chamber (M2 of FIG. 8). Then, the blank mask sample may be transferred to a load lock chamber (M3 of FIG. 8). The load lock chamber may also be in a vacuum state. After the formation of the light shield layer pattern 720a, particles CP1 may be formed on the blank mask sample during a subsequent process.

Referring to FIGS. 8 and 7C, after transferring the blank mask sample from the load lock chamber to a dry etching chamber, the phase shift layer 710 may be dry-etched using the light shield layer pattern 720a as an etch mask (M4 of FIG. 8). As a result, a first etched phase shift layer 710a may be formed. Particles CP1 may be attached to the blank mask sample during the etch process. The particles CP1 may be negatively charged by plasma discharge during the etch process.

The phase shift layer 710 may be non-uniformly etched due to the particles CP1 during the etch process. In an enlarged view of region “B,” region C2 under the particles CP1 may not be etched, but region C1 free of the particles CP1 may be etched. At this time, the phase shift layer 710 may not be fully etched to expose the quartz substrate 700. If the phase shift layer 710 is fully etched by a single etch process, a phase shift layer pattern may be different from the light shield layer pattern 720a.

Referring to FIGS. 8 and 7D, the blank mask sample having the first etched phase shift layer 710a may be transferred to the load lock chamber (M5 of FIG. 8). An examination as to whether a pattern has been completely formed (M6 of FIG. 8) may be taken, if the pattern has not been formed, the particles CP1 on the blank mask sample are removed using the gas injector and the ionizer of the particle removing device described with reference to FIGS. 4A, 4B, and 5 (M61 of FIG. 8). FIG. 7D shows a blank mask sample from which the particles CP1 are removed.

In a process of removing the particles CP1 on the first etched phase shift layer 710a using the ionizer and the gas injector, injected ionized gas passing through the ionizer neutralizes the charged particles CP1 on the first etched phase shift layer 710a. Then, the neutralized particles CP1 may be removed by the injected gas from the gas injector.

In another embodiment, in a process of removing the particles CP1 on the first etched phase shift layer 710a using the ionizer and the gas injector, the ionized gas passes through the gas injector and is injected and neutralizes and concurrently removes the charged particles CP1 on the first etched phase shift layer 710a.

Referring to FIGS. 8 and 7E, the blank mask sample from which the particles CP1 are removed may be transferred from the load lock chamber to the dry etching chamber (M4 of FIG. 8). Then, the first etched phase shift layer 710a may be etched again using the light shield layer pattern 720a as an etch mask. As a result, a second etched phase shift layer 710b may be formed. New particles CP2 may be attached to the blank mask during the etch process. The particles CP2 may be negatively charged by the plasma discharge during the etching process.

In region “B” of the blank mask sample having the second etched phase shift layer 710b, region C2 where the particles CP1 previously existed, and the region C1 free of the particles CP1 described in reference to FIG. 7C may be etched again.

FIGS. 8 and 7F, FIG. 7F illustrates a sectional view of the blank mask sample after the particles CP2 are removed by repeating M5, M6, and M61 of FIG. 8.

Referring to FIGS. 8 and 7G, the etch process for the blank mask sample inside the dry etching chamber, and the particle removing process inside the door chamber as described in reference to FIGS. 7C to 7F are repeated several times as needed to form a phase shift layer pattern 710c exposing the quartz substrate 700 and having the same shape as that of the light shield layer pattern 720a.

Then, the blank mask sample may be transferred from the load lock chamber to the door chamber (M7 of FIG. 8). The interior of the door chamber may be vented to create an atmosphere condition (M8 of FIG. 8). The blank mask sample may be unloaded from the vented door chamber (M9 of FIG. 8).

As described above, the particles attached to the surface of the blank mask sample may be removed, and the etch process may be repeatedly performed to form the phase shift pattern. The etch process and the particle removing process are performed in-situ in example embodiments of the present invention. Therefore, as compared to the prior art, the processes may be performed simply and effectively.

As described above, according to example embodiments of the present invention, particles attached to a surface of an etch mask sample may be removed by a gas injector and an ionizer installed in a door chamber or a load lock chamber of an etching apparatus. Further, as the etch process and the particle removing process, which may be repeatedly performed, are performed in-situ, thereby the fabrication processes may be performed simply and effectively. Therefore, the process time may be reduce, which also may reduce production cost.

The foregoing may be illustrative of example embodiments of the present invention and may not to be construed as limiting thereof. Although example embodiments have been described, those skilled in the art will readily appreciate that many modifications may be possible without materially departing from the novel teachings and aspects of the example embodiments of the present invention. Accordingly, all such modifications are intended to be included within the scope of the example embodiment of the present invention It is understood that the foregoing are illustrative of the example embodiments present invention and are not to be construed as limited to the example embodiments disclosed, and that modifications to the disclosed embodiments, as well as other embodiments, are intended to be included within the scope of the present invention.

What is claimed is:

1. A dry etching apparatus having a particle removing device, comprising:
a dry etching chamber;
a door chamber;
a load lock chamber coupled to connect the dry etching chamber to the door chamber;
a particle removing device configured inside the door chamber or the load lock chamber; and
a gas supplying source coupled to the door chamber or the load lock chamber and adapted to supply gas to the particle removing device.

2. The dry etching apparatus according to claim 1, wherein the particle removing device includes a gas injector and an ionizer configured in parallel with each other.

3. The dry etching apparatus according to claim 2, wherein the gas injector supplies nitrogen, air, CO₂ ice, or H₂O gas to a blank mask sample.

4. The dry etching apparatus according to claim 2, wherein the ionizer supplies air to a blank mask sample.

5. The dry etching apparatus according to claim 1, wherein the particle removing device includes an integrally formed gas injector and ionizer.

6. The dry etching apparatus according to claim 1, further including a filter configured on the gas supplying source to clean and filter the gas.

7. The dry etching apparatus according to claim 1, wherein the dry etching chamber, the load lock chamber, and the door chamber each includes a substrate stage adapted to mount a blank mask sample thereon.

8. The dry etching apparatus according to claim 7, wherein the particle removing device is disposed over and at a desired distance from the substrate stage.

9. The dry etching apparatus according to claim 7, wherein the particle removing device includes injection openings and the injection opening are directed toward the substrate stage at a desired angle.

10. The dry etching apparatus according to claim 7, wherein the particle removing device scans along a direction in parallel with the substrate stage.

11. A method of fabricating a phase shift mask, comprising:
etching a phase shift layer on a blank mask sample, the phase shift layer having a light shield layer pattern formed thereon;
examining the blank mask sample to determine whether a pattern has been completely formed; and
removing particles on the blank mask sample by injecting gas thereon in-situ.

12. The method according to claim 11, wherein etching the phase shift layer and removing the particles are repeated at least two times.

13. The method according to claim 11, further including transferring the blank mask sample to a door chamber prior to examining whether the pattern has been completely formed.

14. The method according to claim 11, further including transferring the blank mask sample to a load lock chamber prior to examining whether the pattern has been completely formed.

15. The method according to claim 11, wherein etching the phase shift layer and removing particles are performed in a vacuum condition.

16. The method according to claim 11, wherein the particles are charged by the etching process.

17. The method according to claim 16, wherein removing the particles on the blank mask sample includes:
injecting ionized gas to neutralize the charged particles; and
removing the neutralized particles by injecting the gas.

18. The method according to claim 17, wherein the ionized gas and the gas are concurrently supplied by the injector on the blank mask sample to neutralize and remove the charged particles.

19. The method according to claim 11, wherein supplying the gas includes nitrogen, air, CO₂ ice, or H₂O.

20. The method according to claim 11, wherein supplying the ionized gas includes air.

21. The method according to claim 11, wherein forming the light shield layer pattern forms a chrome light shield layer pattern.

22. The method according to claim 11, wherein removing the particles is in-situ.
